(19) United States
(12) Patent Application Publication
(10) Pub. No.: US 2026/0133501 A1
(43) Pub. Date: May 14, 2026

(54) POSITIONING SYSTEM, LITHOGRAPHIC TOOL AND METHOD FOR POSITIONING A MOVEABLE OBJECT USING A POSITIONING SYSTEM

(71) Applicant: ASML Netherlands B.V., Veldhoven (NL)

(72) Inventors: Rudolf Michiel HERMANS, Eindhoven (NL); Karst BRUMMELHUIS, Utrecht (NL); Adrianus Constantijn DE JONG, Best (NL)

(73) Assignee: ASML Netherlands B.V., Veldhoven (NL)

(21) Appl. No.: 19/119,620

(22) PCT Filed: Sep. 22, 2023
(86) PCT No.: PCT/EP2023/076199

§ 371 Date: Apr. 9, 2025

(30) Foreign Application Priority Data
Nov. 4, 2022 (EP) 22205478.5

(51) Int. Cl. G03F 7/00

(52) U.S. Cl. CPC G03F 7/70725

(57) ABSTRACT

The invention provides a positioning system for positioning a movable object, comprising:
multiple actuators arranged to move the movable object in one or more degrees of freedom, wherein the multiple actuators comprise more actuators than the one or more degrees of freedom,
a control system comprising a controller to provide control signals on the basis of a set-point and/or a control error, and a transformation matrix to transform the control signals into actuator inputs for the multiple actuators,
   wherein the transformation matrix comprises transformation values for each relationship between one of the control signals and one of the actuator inputs, wherein the transformation values are selected in dependence of an intended trajectory of the movable object and/or wherein, in use, the transformation values are adjustable in dependence of one or more actual performance related parameters of the positioning system.

### CROSS-REFERENCE TO RELATED APPLICATION

The application claims priority of EP application 22205478.5 which was filed on 4 Nov. 2022 and which is incorporated herein in its entirety by reference.

FIELD The present invention relates to a positioning system for positioning a movable object. The invention further relates to a method for positioning a movable object using a positioning system.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

In a lithographic apparatus positioning systems may be used to move movable objects along a trajectory. Such positioning system which for example is used to move a substrate support or a patterning device support, comprises an actuator to exert an actuation force on the movable object in an actuation direction, and a control system to provide an actuator input to the actuator.

The control system may comprise a controller, for example a feedback controller and/or a feedforward controller, that provides control signals on the basis of a set-point and/or a control error, i.e. a difference between a set-point and an actual position related value of the movable object. The control system may further comprise a transformation matrix to transform the control signals in control coordinates into actuation signals in actuation coordinates. Such transformation is for example needed when the actuation directions of the actuators do not one-to-one correspond to the directions of movement of the movable object in the control coordinates.

In some embodiments of a positioning system, the positioning system is over-actuated. In an over-actuated positioning system, multiple actuators may be arranged to move the movable object in one or more degrees of freedom, wherein the quantity of actuators is larger than the number of degrees of freedom. In practice, the positioning system may for example have twelve actuators arranged to control a position of the movable object in six degrees of freedom, wherein for each degree of freedom at least two actuators are available to exert an actuation force for movement in the respective degree of freedom, which means having a total of at least twelve actuators.

In an over-actuated positioning system, the actuation force to be exerted by the actuators in a single degree of freedom may therefore be distributed over at least two actuators. As a result, there is freedom for distribution of these actuation forces. This freedom of distribution may be used to limit the peak temperature for each actuator and/or to limit another performance related parameters of the positioning system.

With an increasing demand on the throughput and overlay performance of a lithographic apparatus, there is a need to use a larger variety of trajectories for the substrate support, in particular during the alignment phase in which a plurality of alignment marks provided on the substrate are measured. This larger variety of trajectories causes different loads on the positioning system which makes it more difficult to keep performance related parameters, such as peak temperatures of the actuators below safety thresholds.

### SUMMARY

It is an aim of the invention to provide a positioning system for positioning a movable object that can be used for a larger variety of trajectories of the movable object without exceeding safety thresholds of one or more performance related parameters, such as peak temperatures of the actuators of the positioning system.

According to an aspect of the invention, there is provided a positioning system for positioning a movable object, comprising:
multiple actuators arranged to move the movable object in one or more degrees of freedom, wherein the multiple actuators comprise more actuators than the one or more degrees of freedom,
a control system comprising a controller to provide control signals on the basis of a set-point and/or a control error, and a transformation matrix to transform the control signals into actuator inputs for the multiple actuators,
the transformation matrix comprises transformation values for each relationship between one of the control signals and one of the actuator inputs, wherein the transformation values are selected in dependence of an intended trajectory of the movable object and/or wherein, in use, the transformation values are adjustable in dependence of one or more actual performance related parameters of the positioning system.

According to an aspect of the invention, there is provided a method for positioning a movable object using a positioning system, comprising:
providing control signals on the basis of a set-point and/or a control error;
transforming the control signals into actuator inputs using a transformation matrix, wherein the transformation matrix comprises transformation values for each relationship between one of the control signals and one of the actuator inputs, wherein the transformation values are selected in dependence of an intended trajectory of the movable object and/or wherein, in use, the transformation values are adjusted in dependence of one or more actual performance related parameters of the positioning system; and
actuating multiple actuators of the positioning system using the actuator inputs to move the movable object in one or more degrees of freedom, wherein the multiple actuators comprise more actuators than the one or more degrees of freedom.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a detailed view of a part of the lithographic apparatus of FIG. 1;

FIG. 3 schematically depicts a position control system; FIG. 4 depicts a trajectory of a substrate support during an exposure phase of a lithographic process;

FIG. 5 depicts a trajectory of a substrate support having balanced movements in x-directions and y-directions during an alignment phase of a lithographic process;

FIG. 6 depicts a trajectory of a substrate support having dominant movements in x-direction during an alignment phase of a lithographic process;

FIG. 7 schematically depicts a position control system having a data storage; and

FIG. 8 schematically depicts a position control system having an adjustable transformation matrix.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

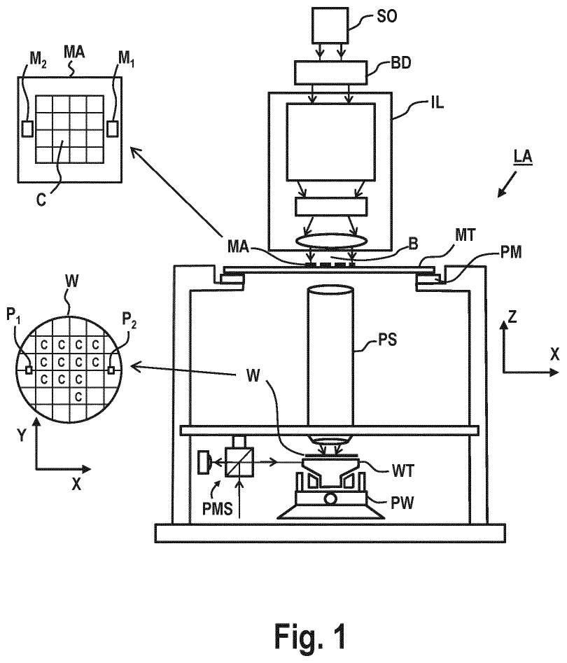

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

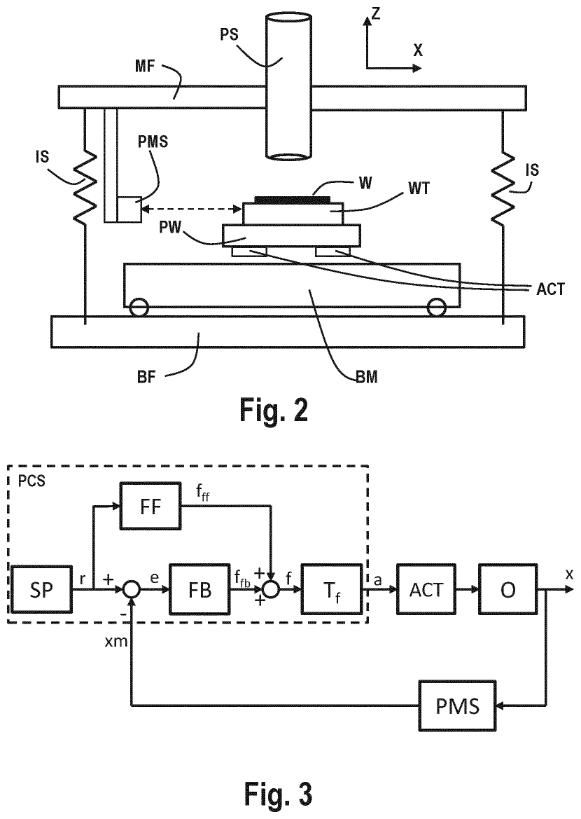

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction of movement. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor. a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads are arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, United States patent U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

As shown in FIG. 2, for the second positioner PW, multiple actuators ACT may be provided to accelerate the substrate support WT in a direction of movement. These actuators ACT may be linear actuators to provide a driving force along a single axis, for example the x-axis. Multiple linear actuators may be applied to provide driving forces along multiple axes. The actuators ACT may comprise a planar actuator to provide a driving force along multiple axes. For example, the planar actuator may be arranged to move the substrate support WT in 6 degrees of freedom.

The actuators ACT may be electro-magnetic actuators comprising at least one coil and at least one magnet. Each of these actuators may be arranged to move the at least one coil relative to the at least one magnet by applying an electrical current to the at least one coil. The actuators ACT may be a moving-magnet type actuator, which have the at least one magnet coupled to the substrate support WT. The actuators ACT may be a moving-coil type actuator which has the at least one coil coupled to the substrate support WT. The actuators ACT may be a voice-coil actuator, a reluctance actuator, a Lorentz-actuator or a piezo-actuator, or any other suitable actuator.

The lithographic apparatus LA comprises a position control system to control the position of the substrate support W.

FIG. 3 shows a control scheme of a movable object O, for example a substrate support WT comprising a position control system PCS. The position control system PCS is arranged to provide actuator inputs a as input signals for the actuators ACT. The actuators ACT will exert an actuation force on the movable object O corresponding to the respective actuator inputs a resulting in an acceleration of the movable object O to a position related value x, such as position, velocity and/or acceleration.

The position control system PCS comprises a set-point generator SP, a feedforward controller FF, a feedback controller FB, and a transformation matrix Tf. The set-point generator SP is arranged to provide a series of set-points to be followed by the controlled object, for example the substrate support WT or the mask support MT. The series of set-points may for instance comprise a series of positions, velocities and/or accelerations that represent an intended trajectory of the movable object O.

The feedforward controller FF may provide a feedforward control signal f_{ff} on the basis of the set-point r provided by the set-point generator SP. The feedback controller FB may provide a feedback control signal f_{fb} on the basis of a control error e, i.e. the difference between the set-point r and the actual position related value xm as measured by a position measurement system PMS. The feedforward signal f_{ff} and the feedback control f_{fb} may be combined into a control signal f which is fed into the transformation matrix T_{f}.

The transformation matrix T_{f} is arranged to transform the control signal f into actuation signals a that are fed into the actuators ACT in order to exert actuation forces on the movable object O in the respective actuation directions. The transformation matrix T_{f} may be part of gain balancing and gain scheduling device that is arranged to carry out gain balancing and gain scheduling steps to provide the transformation of the control signal f into the actuator inputs a.

The gain balancing and gain scheduling steps may for instance provide a transformation of the control signal, e.g. the desired actuator forces, into the actuator input, e.g. current setpoints for the actuators ACT, using a nonlinear function of required force and actual actuator position.

The gain balancing and gain scheduling steps may apply a series of linear controllers, wherein each of the linear controllers is arranged to provide a specific control for a different operating point of the system, e.g. a position of the electromagnetic actuator ACT. On the basis of one or more scheduling variables, the actual operating region of the electromagnetic actuator ACT may be determined, and the associated linear controller may be selected to provide the respective actuator input.

For example, in a positioning system in which a position of a movable object O is controlled in six degrees of freedom, there does not have to be a one-on-one correspondence between the actuation directions of the actuators and the six degrees of freedom in which the position of the movable object O is controlled.

For each relationship between one of the control signals f and one of the actuator inputs a, the transformation matrix T_{f} comprises a transformation value. The transformation value may have a zero value. The transformation matrix T_{f} may be provided in a classic matrix format having columns and rows, but also in any other form in which transformation values are used to define the relationships between the control signals f and the actuator inputs a.

The actuators ACT may form an over-actuated positioning system having multiple actuators arranged to move the movable object in one or more degrees of freedom, wherein the multiple actuators comprise more actuators than the one or more degrees of freedom. In other words, an over-actuated positioning system comprises M actuators to move the movable object in N degrees of freedom, wherein M and N are natural numbers and M>N.

In such over-actuated system, at least two actuators ACT may be arranged to exert an actuation force on the movable object O, in an actuation direction, wherein the actuation directions of the at least two actuators at least partially extend in the same direction such that at least one degree of freedom can be actuated individually by the at least two actuators. In an embodiment, the positioning system may be over-actuated in six degrees of freedom. This means that for each degree of freedom at least two actuators are available to individually move the movable object O in the respective degree of freedom resulting in at least twelve actuators for the whole positioning system. Therefore, the actuation force to be exerted, in an over-actuated positioning system, in a single degree of freedom may be distributed over at least two actuators. Thus, there is freedom for distribution of these actuation forces over the actuators.

The freedom to distribute the actuator forces over the actuators can be used to limit and/or optimize one or more performance related parameters of the positioning system. These one or more performance related parameters may for example comprise peak temperature, actuator current at the least two actuators, peak actuator current, peak actuator voltage, availability of actuators, and/or tracking performance of the positioning system.

The transformation matrix T_{f} that comprises a relationship between the control signals f and the actuator inputs a can be used for this distribution of actuator inputs over the actuators ACT.

The transformation values of the transformation matrix T_{f} may be adjusted to a often followed trajectory of the movable object O, for example for the scanning movements of a substrate support WT during the exposure phase of a lithographic process. This means that the transformation values are determined while taking into account that the substrate support WT will usually follow a predetermined trajectory. Such optimized transformation matrix T_{f} may be effectively used in an exposure phase of a lithographic apparatus in which a trajectory is followed by the substrate support WT having repeatedly scanning movements in the y-direction.

FIG. 4 shows an example of such exposure phase trajectory of a substrate support WT having dominant scanning movements in y-direction.

However, with increasing demands for scanning many alignment marks during the measurement phase of the lithographic process, the variety of trajectories that has to be followed by the substrate support WT is also increased. For example, some trajectories to be followed by the substrate support WT for scanning alignment marks may be relatively dominant in x-directions while others may be relatively dominant in y-directions or balanced in x-directions and y-directions.

Balanced in in x-directions and y-directions means that in such trajectory similar actuation efforts are required in x and y direction.

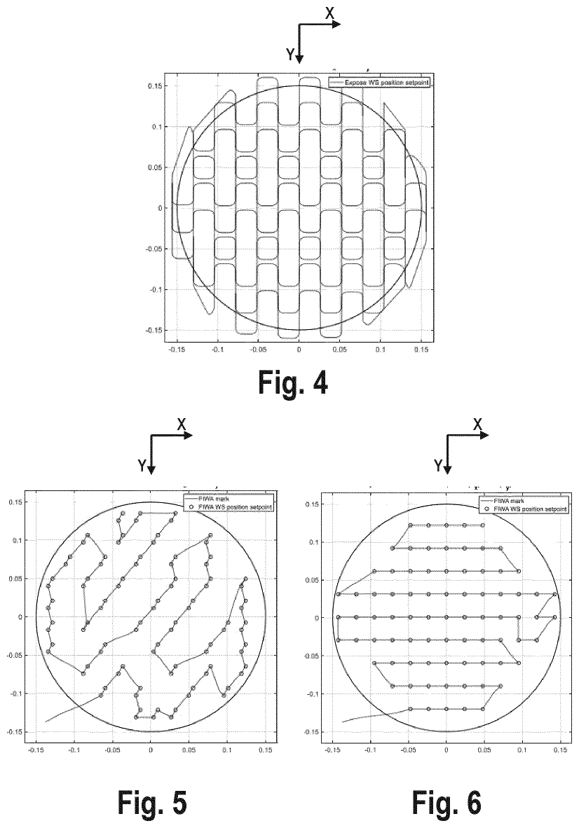

As an example, FIG. 5 shows a trajectory for scanning alignment marks on a substrate having balanced movements in x-directions and y-directions. FIG. 6 shows another trajectory for scanning alignment marks on a substrate having dominant movements in x-direction.

For these different types of trajectories, a transformation matrix T_{f} adjusted to an often followed trajectory may be less suitable. Either the transformation matrix T_{f} is optimized for specific types of trajectories but less suitable for other types of trajectories, or the transformation matrix T_{f} is optimized for all possible trajectories resulting in a generally lower performance.

According to an embodiment of the invention, it is proposed to select the transformation values of the transformation matrix T_{f} in dependence of an intended trajectory of the movable object O. In such embodiment, the transformation values are not optimized for one or more typical trajectories, but in dependence of the intended trajectory the transformation values of the transformation matrix T_{f} are selected for the specific intended trajectory or type of trajectory.

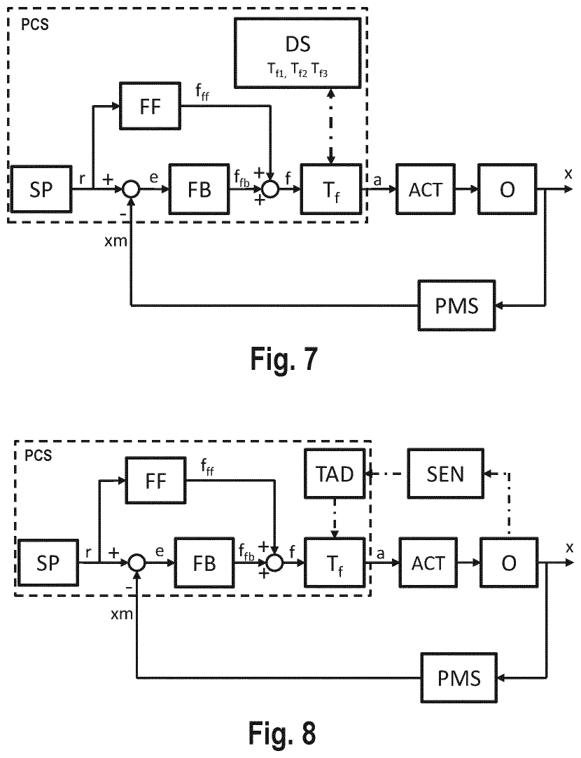

FIG. 7 shows an embodiment of a positioning system having a position control system PCS which is arranged to select the transformation values based on the intended trajectory of the movable object O. In addition to the position control system PCS of FIG. 3, the position control system PCS of FIG. 7 comprises a data storage DS, in which multiple transformation matrices T_{f1}, T_{f2}, T_{f3} with different transformation values are stored. Each of these transformation matrices is optimized for a specific trajectory or a specific type of trajectory to be followed by the movable object O.

For example, the data storage DS comprises a first transformation matrix T_{f1} associated with a first intended trajectory of the movable object O with movements dominant in x-directions, a second transformation matrix T_{f2} associated with a second intended trajectory of the movable object with movements dominant in y-directions, and a third transformation matrix T_{f3} associated with a third intended trajectory of the movable object with balanced movements in x-direction and y-direction.

In use, one of the three transformation matrices T_{f1}, T_{f2}, T_{f3} will be selected taking into account the intended trajectory. The intended trajectory may be matched with a specific type of trajectory for which a transformation matrix T_{f1}, T_{f2}, T_{f3} is available in the data storage DS. For instance, the first transformation matrix T_{f1} may be selected when the intended trajectory is the trajectory shown in FIG. 6 having movements that are dominant in x-direction. This transformation matrix T_{f1} is then used in the position control system PCS as transformation matrix T_{f}.

In practice, the number of transformation matrices T_{f1}, T_{f2}, T_{f3} that can be selected in dependence of the specific type of trajectory to be followed by the movable object O may vary, for example based on the variety of trajectories to be followed and the desired performance of the transformation matrix T_{f}.

In another embodiment, for each trajectory to be followed by the movable object O, a transformation matrix may be determined with transformation values optimized for that specific trajectory. This transformation matrix can be calculated each time the movable object O will follow a trajectory, but it may be more efficient to store such a transformation matrix for a specific trajectory, once calculated, in the data storage DS, such that this transformation matrix can be selected from the data storage DS each time the movable object O should follow this specific trajectory. In this embodiment, the data storage DS will comprise a transformation matrix for each trajectory that was followed by the movable object O with specifically optimized transformation values for that trajectory.

FIG. 8 shows an alternative embodiment of a positioning system. The positioning system of FIG. 8 comprises a position control system PCS which is arranged to adjust, in use, the transformation values of the transformation matrix T_{f} based on one or more actual performance related parameters of the positioning system.

In addition to the control scheme of the positioning system shown in FIG. 3, the positioning system of FIG. 8 comprises a sensor SEN and a transformation value adjustment device TAD. The sensor SEN is arranged to measure one or more actual performance related parameters of the positioning system. The one or more performance related parameters for example comprise peak temperature, actual actuator current at the least two actuators, peak actuator current, peak actuator voltage, availability of actuators, and/or tracking performance.

The measured performance related parameters are fed into the transformation value adjustment device TAD. The transformation value adjustment device TAD may adjust the transformation values, for example to keep the respective measured performance related parameters below a safety threshold and/or to keep performance related parameters at a desired level. For example, sensors SEN may be provided to measure the peak temperatures of all actuators ACT and the transformation value adjustment device TAD may be arranged to adjust the transformation values to keep the actuators ACT at the same temperature.

The transformation value adjustment device TAD may be arranged to periodically adjust the transformation values, for example every 1 or 2 seconds. Alternatively, the transformation value adjustment device TAD may be arranged to adjust the transformation values when certain values of the measured performance related parameters are reached.

Due to the adjustment of the transformation values to the measured performance related parameters the transformation matrix T_{f} may automatically adapt to the movements made by the substrate support during different trajectories of the substrate support WT. This inline adjustment of the transformation values of the transformation matrix T_{f} may therefore effectively be used to provide optimized control for different trajectories of the substrate support WT that typically may be used during alignment phases of a lithographic apparatus.

The in line adjustment of the transformation values of the transformation matrix T_{f} based on the measured performance related parameters may be undesired during an exposure phase of a lithographic apparatus as the adjustment of the transformation values may have an effect on the imaging quality. To have a constant imaging quality, the transformation value adjustment device TAD may therefore be arranged not to adjust the transformation values during the exposure phase.

Furthermore, since the trajectories of the substrate support WT during exposure phase are typically relatively similar, there is less need to adjust the transformation values during the exposure phase.

Also, during alignment phase, it is possible that the adjustment of the transformation values leads to a time-varying performance during settling of the positioning control system to the adjusted transformation values. This effect can be reduced by selecting an appropriate update rate of the transformation values and/or by limiting the bandwidth of the transformation value adjustment device TAD.

Hereinabove, a position control system has been described in which the transformation values of a transformation matrix are selected in dependence of an intended trajectory of the movable object and/or wherein, in use, the transformation values are adjusted in dependence of one or more actual performance related parameters of the positioning system. The position control system may also be applied in any other over-actuate positioning system for movable objects, such as patterning device supports, movable objects of projection system and substrate support that are applied in other processes, such as substrate measurement processes.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-20. (canceled)

21. A positioning system for positioning a movable object, comprising:
multiple actuators arranged to move the movable object in one or more degrees of freedom, wherein the multiple actuators comprise more actuators than the one or more degrees of freedom;
a control system comprising a controller to provide control signals on the basis of a set-point and/or a control error, and a transformation matrix to transform the control signals into actuator inputs for the multiple actuators; and
wherein the transformation matrix comprises transformation values for each relationship between one of the control signals and one of the actuator inputs, wherein the transformation values are selected in dependence of an intended trajectory of the movable object and/or wherein the transformation values are adjustable in dependence of one or more actual performance related parameters of the positioning system.

22. The positioning system of claim 21, wherein the control system comprises a data storage comprising multiple transformation matrices with different transformation values stored therein, and wherein the control system is arranged to use one of the multiple transformation matrices in dependence of the intended trajectory of the movable object.

23. The positioning system of claim 22, wherein the multiple transformation matrices comprise:
a first transformation matrix associated with a first intended trajectory of the movable object with movements dominant in x-directions,
a second transformation matrix associated with a second intended trajectory of the movable object with movements dominant in y-directions, and
a third transformation matrix associated with a third intended trajectory of the movable object with balanced movements in x-direction and y-direction.

24. The positioning system of claim 21, wherein the positioning system comprises one or more sensors to measure the one or more actual performance related parameters, and wherein the control system is arranged to adjust the transformation values on the basis of the measured one or more actual performance related parameters.

25. The positioning system of claims 21, wherein the transformation values are determined to optimize one or more performance related parameters of the positioning system.

26. The positioning system of claim 21, wherein the one or more performance related parameters comprise actual actuator current of a respective actuator, peak actuator current, peak actuator voltage, availability of actuators, and/or tracking performance.

27. The positioning system of claim 21, wherein the intended trajectory of the movable object is represented by a series of set-points for the movement of the movable object.

28. The positioning system of claim 21, wherein the positioning system comprises at least seven actuators to actuate the movable object in six degrees of freedom.

29. The positioning system of claim 21, wherein the positioning system is arranged to actuate the movable object in six degrees of freedom, and wherein for each degree of freedom at least two actuators of the multiple actuators are arranged to individually move the movable object in the corresponding each degree of freedom.

30. The positioning system of claim 21, wherein the movable object is an optic element in a projection system of a lithographic apparatus, a stage to support a substrate, or a stage to support a patterning device.

31. A lithographic tool, comprising the positioning system of claim 21.

32. A method for positioning a movable object using a positioning system, comprising:
providing control signals on the basis of a set-point and/or a control error;
transforming the control signals into actuator inputs using a transformation matrix, wherein the transformation matrix comprises transformation values for each relationship between one of the control signals and one of the actuator inputs, wherein the transformation values are selected in dependence of an intended trajectory of the movable object and/or wherein the transformation values are adjusted in dependence of one or more actual performance related parameters of the positioning system; and
actuating multiple actuators of the positioning system using the actuator inputs to move the movable object in one or more degrees of freedom, wherein the multiple actuators comprise more actuators than the one or more degrees of freedom.

33. The method of claim 32, further comprising storing, in a data storage of the control system, multiple transformation matrices with different transformation values, and using one of the multiple transformation matrices in dependence of the intended trajectory of the movable object.

34. The method of claim 32, wherein the method comprises:
measuring the one or more actual performance related parameters, and adjusting the transformation values on the basis of the measured one or more actual performance related parameters.

35. The method of claim 32, comprising determining the transformation values to optimize one or more performance related parameters of the positioning system.

36. The method of claim 32, wherein the one or more performance related parameters comprise actual actuator current at the least two actuators, peak actuator current, peak actuator voltage, availability of actuators, and/or tracking performance.

37. The method of claim 31, wherein the intended trajectory of the movable object is represented by a series of set-points for the movement of the movable object.

38. The method of claim 32, wherein the positioning system is arranged to actuate the movable object in six degrees of freedom, and wherein for each degree of freedom at least two actuators are arranged to individually move the movable object in this degree of freedom.

39. The method of claim 32, further configured to move an optic element in a projection system of a lithographic apparatus, a stage to support a substrate, or a stage to support a patterning device as the movable object.

40. The method of claim 32, wherein the method is used in a lithographic process comprising an exposure phase, wherein during the exposure phase the transformation matrix and its transformation values are not changed.
